(19) United States
(12) Patent Application Publication
(10) Pub. No.: US 2017/0221960 A1
(43) Pub. Date: Aug. 3, 2017

(54) CONTACT IMAGE SENSOR

(71) Applicant: SunASIC Technologies, Inc., New Taipei City (TW)

(72) Inventors: Chi Chou LIN, Taipei (TW); Zheng Ping HE, Taipei (TW)

(73) Assignee: SunASIC Technologies, Inc., New Taipei City (TW)

(21) Appl. No.: 15/415,934

(22) Filed: Jan. 26, 2017

Related U.S. Application Data
(60) Provisional application No. 62/290,576, filed on Feb. 3, 2016.

(51) Int. Cl. H01L 27/146; H01L 27/32; G06K 9/00; H01L 27/148

(52) U.S. Cl. CPC H01L 27/14678; H01L 27/14625; H01L 27/14643; H01L 27/14806; H01L 27/14629; H01L 27/3227; G06K 9/0004; G06K 9/00087

(57) ABSTRACT

A contact image sensor is disclosed in the present invention. The contact image sensor includes: a substrate; an array of sensing units, formed above the substrate; a first insulation structure, formed over the sensing units and the substrate; a number of focusing units, formed above the first insulation structure, each focusing unit is aligned above a corresponding sensing unit with the first insulation structure sandwiched therebetween; a conductive metal layer, linked to a control circuit; an array of Organic Light-Emitting Diode (OLED) units, formed above the conductive metal layer and connected thereto; a transparent conductive layer, formed above the array of OLED units, and connected to the control circuit to control the statuses of the OLED units; and a transparent insulation structure, formed above the transparent conductive layer.

### FIELD OF THE INVENTION

The present invention relates to a contact image sensor. Especially, the present invention relates to a contact image sensor having Organic Light-Emitting Diodes (OLED) units as a light source to obtain an image of a surface of an object. Preferably, the object is a finger and the contact image sensor works a fingerprint reader.

### BACKGROUND OF THE INVENTION

Optical image sensors, especially fingerprint image sensors, are very popular in applications of security and personnel identification. The optical sensors capture a digital image of the fingerprint using visible or infrared light. Typical optical image sensors use light-emitting diode (LED) as a light source and a charge-coupled device (CCD) camera as a receiver, and often comprises one or more lens and prisms to form an optical path. Due to the physical space required by the components and optical path, the size of the device is usually large that it is unlikely to be used in portable applications, such as smartphones or IC cards. Another disadvantage of the lens/prism-based optical sensor is the optical distortion that requires significant overhead to calibrate.

Organic light-emitting diode (OLED) technology has developed rapidly recently and is able to meet the requirement of a small and/or portable image sensor (as a light source). OLEDs have good energy efficiency and response time, and can be much more compact than other light emitting devices. Most of OLEDs are mainly used in display panels made by matured manufacturing process. For example, the fabrication of OLEDs may utilize transfer-printing technology to print OLED layers onto a flat substrate, such as glass, or a flexible substrate, such as polyethylene terephthalate (PET). Fabricating OLED onto a silicon substrate, such as a wafer of CMOS sensors, is a fairly new technology.

In order to make a fingerprint reader compact and portable, an innovative optical contact image sensor combining OLEDs onto CMOS image sensing chip to reduce the size of the typical lens/prism-based optical sensor is desired.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In order to settle the problems above by introducing the optical contact image technique, an innovative contact image sensor is disclosed. The contact image sensor, comprising: a substrate; an array of sensing units, formed above the substrate; a first insulation structure, formed over the sensing units and the substrate; a number of focusing units, formed above the first insulation structure, each focusing unit is aligned above a corresponding sensing unit with the first insulation structure sandwiched therebetween; a conductive metal layer, linked to a control circuit; an array of Organic Light-Emitting Diode (OLED) units, formed above the conductive metal layer and connected thereto; a transparent conductive layer, formed above the array of OLED units, and connected to the control circuit to control the statuses of the OLED units; and a transparent insulation structure, formed above the transparent conductive layer.

Preferably, the focusing units are pinholes formed on the conductive metal layer.

Preferably, the contact image sensor further includes a second insulation structure, formed between the focusing units and the conductive metal layer;

Preferably, the OLED units includes a hole transport layer, for receiving holes from the conductive metal layer; an electron transport layer, for receiving electronics from the transparent conductive layer; and an emissive layer, formed between the hole transport layer and the electron transport layer, for emitting light when working voltage is provided.

Preferably, the sensing unit is a CMOS (Complementary Metal-Oxide-Semiconductor) image cell or a CCD (Charge-Coupled Device) image cell.

Preferably, the focusing unit is a pinhole.

Preferably, the conductive metal layer is made of a metallic material.

Preferably, the metallic material is copper, aluminum, gold, or alloy thereof.

Preferably, the first insulation structure and the second insulation structure are not opaque.

Preferably, the sensing units and the OLED units are interleaved from the top view of the contact image sensor.

Preferably, the light beams from the OLED units are reflected by an object contacting the transparent insulation structure and pass through the focusing units to be received by the sensing units.

Preferably, the sensing units are activated sequentially to receive reflected light beams out of the OLED units.

Preferably, when one sensing unit is activated, one or more corresponding OLED units are turned on so that the best quality of an image formed by the reflected light beams are able to be obtained.

Preferably, the transparent conductive layer is made of Indium Tin Oxide (ITO).

Preferably, the focusing units are formed in a layer of opaque material.

Preferably, the opaque material is metal.

Preferably, the conductive metal layer comprises a plurality of wires, each connecting to a row or a column of OLED units.

The present invention uses OLED as the light source. It makes the whole contact image sensor compact. Other than the build-in self-calibration for the uniformity of light intensity, the contact image sensor does not need optical calibration. Most important of all, the cost of the contact image sensor can be lower than that of the conventional one.

### BRIEF DESCRIPTION OF THE DRAWINGS

FIG. 1 is a perspective view of an embodiment of a contact image sensor and a first method to obtain an image according to the present invention.

FIG. 2 is a perspective view of an embodiment of a contact image sensor with an additional protective layer according to the present invention.

FIG. 3 is a perspective view of an embodiment of a contact image sensor with an additional protective layer and a second operation method to obtain an image according to the present invention.

FIG. 4 is a top view of the contact image sensor.

FIG. 5 is a top view of another embodiment of the contact image sensor according to the present invention.

FIG. 6 is a cross-section view of the embodiment in FIG. 5.

FIG. 7 is a top view of still another embodiment of the contact image sensor.

### DETAILED DESCRIPTION OF THE PREFERRED EMBODIMENTS

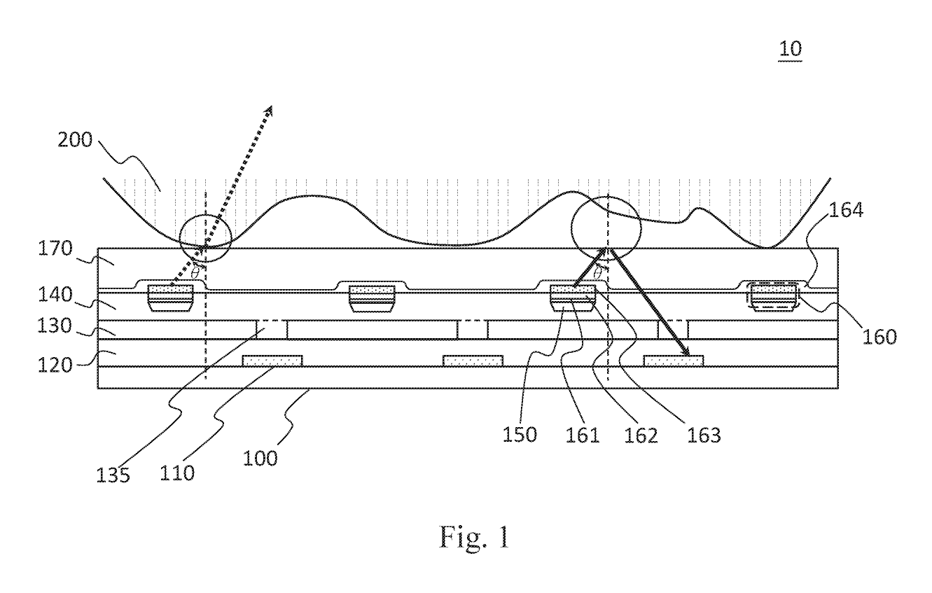

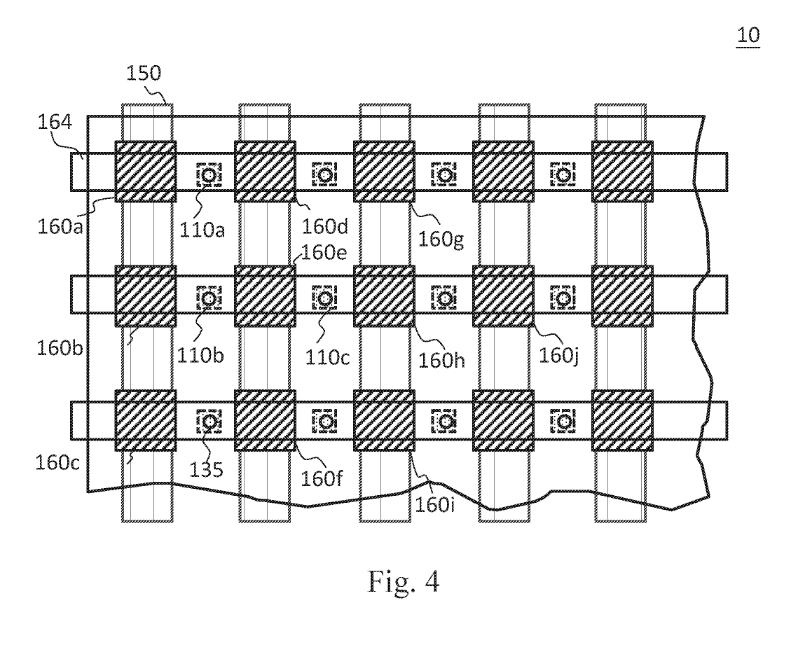

An embodiment according to the present invention is shown in FIG. 1 and FIG. 4. FIG. 1 is a perspective view of a contact image sensor 10 and FIG. 4 is a top view of the contact image sensor 10. Preferably, the contact image sensor 10 is a contact optical fingerprint sensor which can fetch users' fingerprint. The contact image sensor 10 basically includes main elements of a substrate 100, an array of sensing units 110, a first insulation structure 120, a number of focusing units 135, a second insulation structure 140, a conductive metal layer 150, an array of Organic Light-Emitting Diode (OLED) units 160 and a transparent insulation structure 170. The contact image sensor 10 may have other functional elements, such as I/O pads or logic circuits. However, these functional elements are not the key roles in the present invention and will not be described. The functionality of the main elements and the architecture of the contact image sensor 10 are illustrated below.

The substrate 100 can be made of any materials used to form a base structure of an integrated circuit. The sensing units 110 are formed above the substrate 100. There are five columns and three rows of sensing units 110 (15 units in total) shown in FIG. 4. This is for illustrative purpose only. In fact, the number can be as many as a design requires, for example, 200×200 units in an array. Each sensing unit 110 has a sensing surface upwards. It means the sensing unit 110 can receive reflected light beams emitted by the OLED units 160 from the top. The sensing unit 110 may be a CCD (Charge-coupled Device) image cell or a CMOS (Complementary Metal-Oxide-Semiconductor) image cell. It should be noticed that there is a control circuit (not shown) arranged around the sensing units 110 to control the sensing units 110 and fetch the outputs of the sensing units 110. It is omitted from FIG. 1 just to simplify the illustration.

The first insulation structure 120 is formed over the sensing units 110 and the substrate 100. In order to let light beams pass through for the sensing units 110, the first insulation structure 120 cannot be made of opaque material. Namely, the first insulation structure 120 should be transparent or translucent. Transparent materials are preferred.

There are a number of focusing units 135 formed above the first insulation structure 120. Each focusing unit 135 is aligned above a corresponding sensing unit 110 with the first insulation structure 120 sandwiched therebetween. The focusing units 135 should have the same number as that of the sensing units 110. In fact, each focusing unit 135 is a pinhole. The focusing units 135 are pinholes formed in an opaque material layer 130. Preferably, the opaque material layer 130 is a layer of metal. It can be formed by using standard semiconductor manufacturing processes, such as sputter deposition and photolithography.

The second insulation structure 140 is formed over the focusing units 135. Namely, the second insulation structure 140 is over the whole opaque material layer 130. Similarly, the second insulation structure 140 is used to pass light beams for the sensing units 110. It cannot be opaque. The second insulation structure 140 should be transparent or translucent. Transparent materials are preferred.

The conductive metal layer 150 is a key part of the contact image sensor 10. It is formed at a layer above the focusing units 135 without overlapping the focusing units 135. The conductive metal layer 150 is linked to a control circuit (not shown) which is not limited to be inside the contact image sensor 10. Literally, it can be known that the conductive metal layer 150 is made of a metallic material. Preferably, the metallic material is copper, aluminum, gold, or alloy of these metals. The conductive metal layer 150 may connect to all OLED units 160 to control the statuses (on/off or brightness) of the OLED units 160. In practice, the conductive metal layer 150 may be formed in a number of wires. Each wire connects a row/column of OLED units 160. Thus, the row/column of OLED units 160 can be controlled to emit at the same time. Multiple rows/columns of OLED units 160 can be turned on sequentially. The operation of the wires formed by the conductive metal layer 150 is synchronized with the control unit. Thus, when one sensing unit 110 is activated, the corresponding OLED units 160 emits light beams to an object 200 contacting the transparent insulation structure 170 and the reflected light beam is received by the sensing unit 110.

The array of OLED units 160 are formed on the conductive metal layer 150 and connected thereto. Usually, each OLED unit 160 comprises three main portions: a hole transport layer 161, an emissive layer 162, and an electron transport layer 163. The hole transport layer 161 is formed between the conductive metal layer 150 and the emissive layer 162 which is formed under the electron transport layer 163, as shown in FIG. 1. The contact image sensor 10 further has a transparent conductive layer 164 formed above the OLED units 160 to act as a cathode of the OLED unit 160, while the conductive metal layer 150 acts as an anode of the OLED units 160, for allowing the OLED units 160 to be connected to the control circuit so that the statuses of the OLED units 160 can be controlled. The contact image sensor 10 can be formed in a single manufacturing process or can be formed in separated processes, for example, the OLED units 160 and the conductive metal layer 150 may be formed separately in different manufacturing processes and afterwards be integrated into one. The hole transport layer 161 receives holes from the conductive metal layer 150 and the electron transport layer 163 receives electronics from the transparent conductive layer 164. Thus, when a working voltage is provided to the OLED unit 160 (through the conductive metal layer 150 and the transparent conductive layer 164), the emissive layer 162 can emit light. The hole transport layer 161 and the electron transport layer 163 are conductive layers in a commonly seen OLED, formed for enhancing luminous efficiency. Yet in some OLED implementation, there might be missing hole or electron transport layer. The structure of the OLED unit 160 is not limited by the present invention. Preferably, the transparent conductive layer 164 is made of Indium Tin Oxide (ITO).

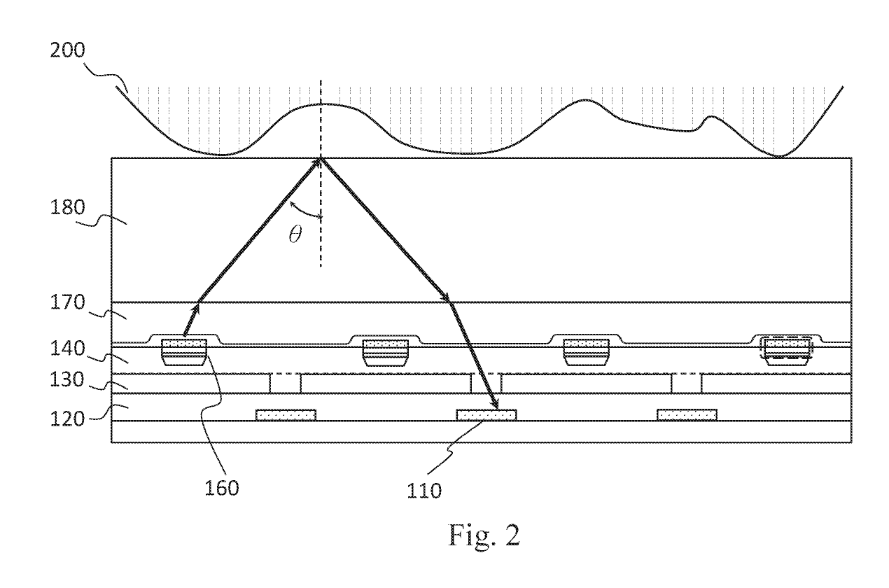

The transparent insulation structure 170 is formed on the transparent conductive layer 164. It has a flat top surface and for resting the object 200. The light beams from the OLED units 160 are reflected by the object 200 contacting the transparent insulation structure 170 and pass through the focusing units 135 to be received by the sensing units 110. The transparent insulation structure 170 provides a basic protection of the structures below it. There might optionally be a transparent protective layer over the transparent insulation structure 170 to enhance the protection of the top surface of the contact image sensor 10 from scratching. Please refer to FIG. 2. An additional transparent protective layer 180 covers the top surface of the contact image sensor 10. The additional transparent protective layer 180 is made of transparent and robust material, such as glass, sapphire, or ceramics. The optical path in the FIG. 2 is obviously different from that in the FIG. 1, and will be described later. It should be emphasized that the transparent insulation structure 170 is made of transparent material to minimize energy dissipation of the light from the OLED units 160.

In FIG. 4, the sensing units 110 and the OLED units 160 are interleaved (viewing from the top of the contact image sensor 10). However, not necessarily the same as the arrangement of the sensing units 110, the number of OLED units 160 may differ from that of the sensing units 110. The number of the sensing units 110 and the OLED units 160 are not necessary to be the same. This will be illustrated in another embodiment later.

Light beams emitted from the OLED units 160 are reflected by the object 200. The reflected light beams pass through the focusing unit 135 and then caught by the sensing unit 110. Each sensing unit 110 receives the reflected light beams and transfers them to an electronic signal. The electronic signals generated by the array of the sensing units 110 are then digitized and arranged to form an output image. There are several methods to obtain a good image of the surface of the object 200. Here, two of these methods are given as examples, but the methods need not to be limited to these examples as long as good image quality is achieved. Also, various methods can be combined to enhance one another. For example, optical characteristics of human skin and/or living tissue may also be utilized for fingerprint anti-spoofing. Oxygen saturation may be a good anti-spoofing method. By monitoring absorption of light around two different wavelengths, 660 nm and 940 nm, oxygen saturation of the blood in the skin of a fingertip can provide anti-spoof information.

Please refer to FIG. 1. FIG. 1 gives a first method to obtain the image of the object 200. While an object with an uneven surface, such as a finger, contact the top surface of the image sensor, incident light beams (to the finger) may refract and diffuse at where the ridge located and reflect at where the valley located. This is because human skin and air have different refract index. Total internal reflection may happen when a correct incident angle is chosen. Therefore, the activated OLED unit 160 and sensing unit 110 should be spaced to realize an angle θ between the direction of the light beam and the normal direction of the top surface. Theoretically, the best image quality is achieved when the incident angle θ is slightly larger than the critical angle of the boundary where the object 200 is placed.

FIG. 1 shows one optical path (solid line) of the beam(s) emitted from one OLED unit 160, reflected by the object (valley) 200, focused by one focusing unit 135, and received by one sensing unit 110. Another optical path (dotted line) representing the light beam(s) refracted and diffused by the object (ridge) 200. The boundary mentioned in the last paragraph is the top surface of the transparent insulation structure 170.

FIG. 2 shows one optical path of the contact image sensor with an additional protective layer 180. The light beam emits from one OLED unit 160, refracted by the boundary between the transparent insulation structure 170 and the additional protective layer 180, reflected by the object (valley) 200, refracted by the boundary, focused by one focusing unit 135, and received by one sensing unit 110. The boundary the object 200 is placed is the top surface of the additional protective layer 180.

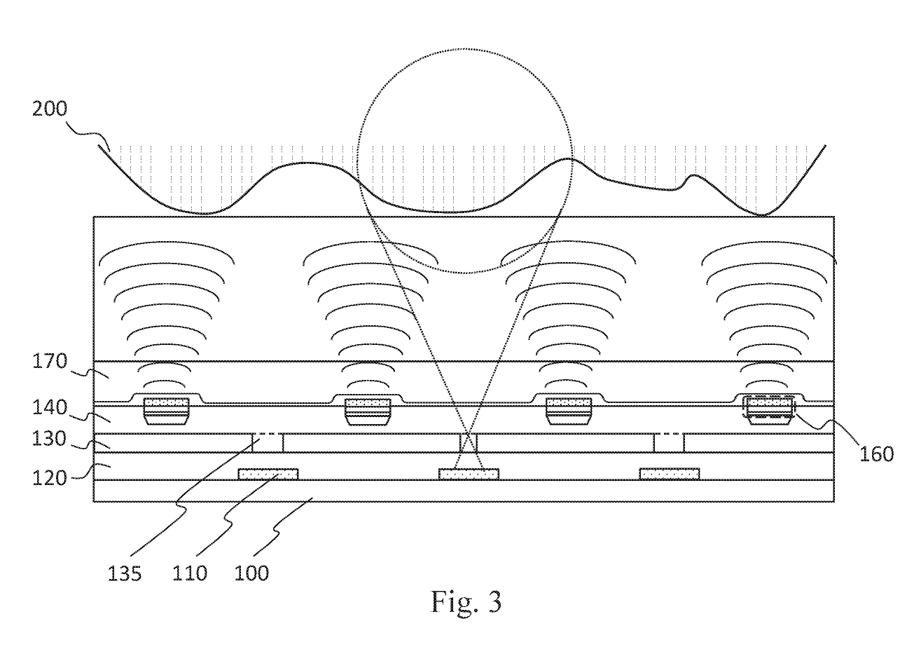

Please refer to FIG. 3. FIG. 3 gives another method to obtain an image of the object 200. The method does not utilize the phenomena of total internal reflection. The contact image sensor works as a CCD or CMOS camera with an array of focusing units 135. Each sensing unit 110 has a focusing unit 135 located above it. The OLED units 160 are used to illuminate the object 200. Here, the focusing unit 135 is a pinhole designed to receive light beams from a small area of the object 200 above each focusing unit. Dotted lines show the range of light beams that can reach the sensing unit 110 from the object. The area is less than or equal to an area of 50 um×50 um.

The optical path in FIG. 1 and FIG. 3 are simplified and are used for illustration purpose. The real optical path is designed under different conditions, e.g. thickness and the material of each layer, for the contact image sensor 10 to obtain the best quality of the image of the object 200.

Please refer to FIG. 1 and FIG. 2. While the contact image sensor 10 is operated under the first method, the OLED units 160 is turned on in a predetermined order to achieve reliable image quality. To be more precisely, the sensing units 110 are activated sequentially and the corresponding OLED units 160 providing the best quality of image for one specific sensing unit 110 are turned on while that specific sensing unit 110 is activated. The corresponding OLED units 160 may be obtained by empirical tests and/or theoretical calculation following the methods mentioned previously. The incident angle θ may range from 30 degrees to 85 degrees, depending on the optical path designed for the contact image sensor. In other words, OLED units 160 that provide light in the range of incident angles may be turned on at the same time. On the other hand, for the sake of power saving, it is better to minimize the number of OLED units that emit light. Therefore, a proper rule for operating the OLED units 160 that balanced light intensity and power saving will be chosen. It is clear from FIG. 2 that the OLED unit 160 that provides light is not necessarily adjacent to the sensing units 110. The OLED unit 160 may be at any location as long as it provides the best quality of image for the sensing units 110.

An example is illustrated in FIG. 4. Assume the best quality of image for one sensing unit 110 is achieved by turning on one of the diagonal OLED units 160. When the sensing unit 110a is activated, it can be chosen to turn on the OLED units 160b, and 160e, accordingly. Similarly, when the sensing unit 110b is activated, the OLED units 160a, 160c, 160d and 160f are turned on; when the sensing unit 110c is activated, the OLED units 160d, 160f, 160g, and 160i are turned on. Here, it is not to emphasize the sequence of sensing units activated but the OLED units. In another example, assume six OLED units 160d, 160f, 160g, 160i, 160b and 160j provide incident light for the sensing unit 110c to achieve the best image quality. For the sake of power saving, some of the OLED units, e.g. 160b and 160j, may not be turned on while the sensing unit 110c is activated as long as an acceptable light intensity for good image quality is achieved.

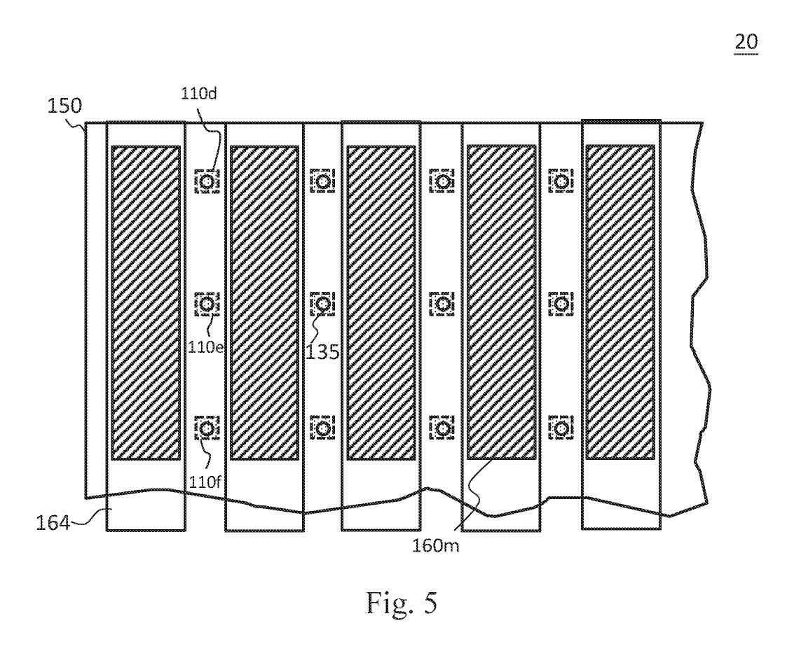

In another embodiment, the sensing units and OLED units 160 may be arranged in different numbers and shapes. Please refer to FIG. 5. A contact image sensor 20 is shown with the same elements used in the previous embodiment. The difference is that, the OLED units 160 are in the shape of a strip across the entire row or column, rather than dots. Clearly, the number of the OLED units 160 is different from the number of sensing units 110. In this embodiment, three sensing units 110d, 110e and 110f are used for illustration. If the reflected light beams form the best quality of image coming from the OLED unit 160m, when the OLED unit 160h is turned on, the sensing units 110d, 110e, and 110f, etc. are activated one by one, sequentially. The charges generated in each sensing units 110 while light beams are reflected back by the object are then converted to a digital image value by a read-out circuit (not shown). The read-out circuit usually comprises an integration capacitor, a voltage follower, and an analog-to-digital converter. The read-out method(s) are commonly used in various image sensors, and will be skipped here.

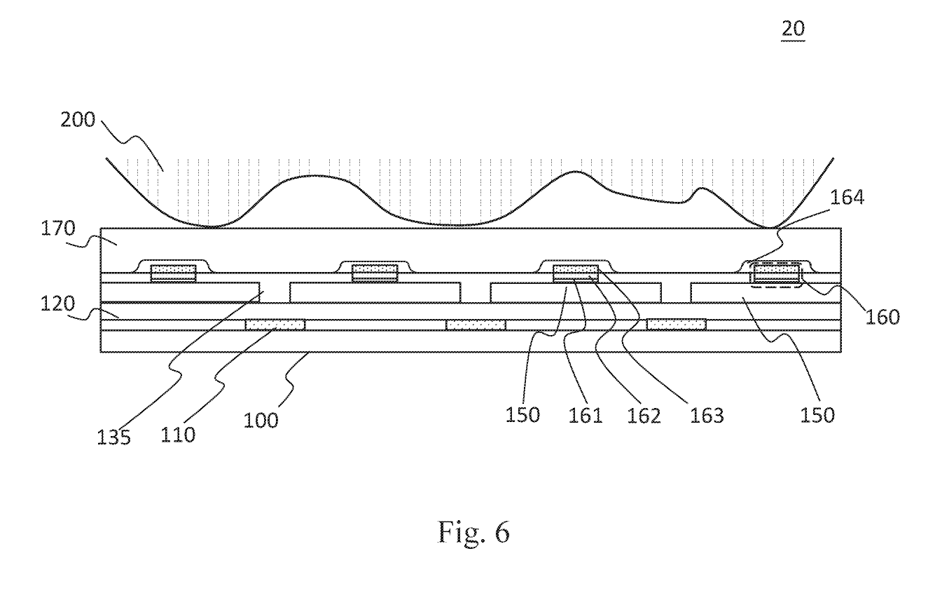

Please refer to FIG. 6. In this embodiment, the focusing units 135 and the conductive layer 150 that works as the anode of the OLED unit 160m may be formed in one structure, i.e. a metal plate with an array of pinholes. For example, the focusing units 135 can be pinholes formed on the conductive metal layer 150. The transparent conductive layer 164 (ITO) is also slightly different from that in the previous embodiment. The transparent conductive layer 164 is formed above each OLED unit 160m and is parallel to the direction of the strip-shaped OLED units 160. Because the OLED units 160 are strip-shaped, the statuses (on/off or brightness) of the OLED units 160m can be controlled only by the corresponding transparent conductive strip (ITO).

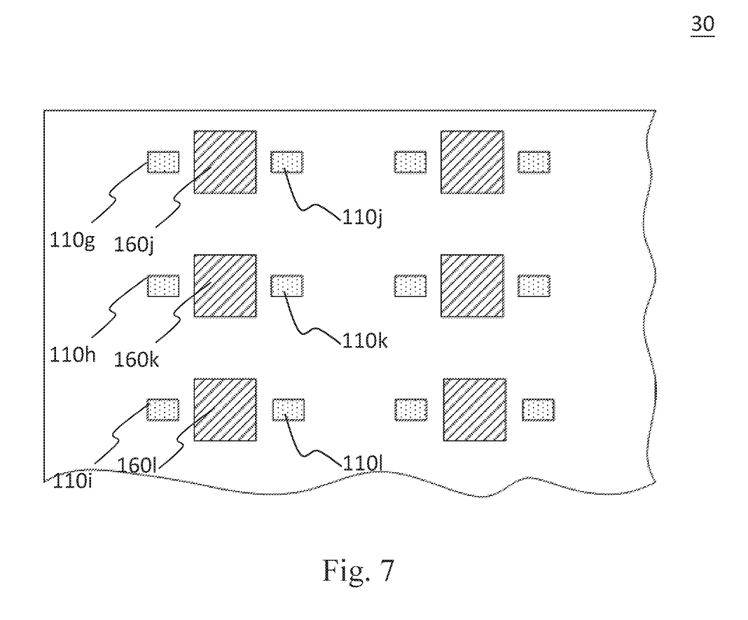

In another embodiment, the sensing units and OLED units would have another form of arrangement with different numbers. Please see FIG. 7. A contact image sensor 30 is shown with the same elements used in the previous embodiment. The difference to the previous embodiments is that two OLED units are placed in between each pair of adjacent sensing units, and the total number of OLED units doubles the number of sensing units. Under this arrangement, the operation sequence of the OLED units 160 and the sensing units 110 are different from that in the previous embodiments. When the OLED unit 160j is turned on, the sensing units 110g and 110j should be activated to receive light. When the OLED unit 160k is turned on, the sensing units 110h and 110k should be activated to receive light. When the OLED unit 160l is turned on, the sensing units 110i and 110l should be activated on to received light. This way can reduce the number of OLED units 160 been used.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. A contact image sensor, comprising:
a substrate;
an array of sensing units, formed above the substrate;
a first insulation structure, formed over the sensing units and the substrate;
a plurality of focusing units, formed above the first insulation structure, each focusing unit is aligned above a corresponding sensing unit with the first insulation structure sandwiched therebetween;
a conductive metal layer, linked to a control circuit;
an array of Organic Light-Emitting Diode (OLED) units, formed above the conductive metal layer and connected thereto;
a transparent conductive layer, formed above the array of OLED units, and connected to the control circuit to control the statuses of the OLED units; and
a transparent insulation structure, formed above the transparent conductive layer.

2. The contact image sensor according to claim 1, wherein the focusing units are pinholes formed on the conductive metal layer.

3. The contact image sensor according to claim 1, further comprising:
a second insulation structure, formed between the focusing units and the conductive metal layer.

4. The contact image sensor according to claim 1, wherein the OLED comprising:
a hole transport layer, for receiving holes from the conductive metal layer;
an electron transport layer, for receiving electronics from the transparent conductive layer; and
an emissive layer, formed between the hole transport layer and the electron transport layer, for emitting light when working voltage is provided.

5. The contact image sensor according to claim 1, wherein the sensing unit is a CMOS (Complementary Metal-Oxide-Semiconductor) image cell or a CCD (Charge-Coupled Device) image cell.

6. The contact image sensor according to claim 1, wherein the conductive metal layer is made of a metallic material.

7. The contact image sensor according to claim 5, wherein the metallic material is copper, aluminum, gold, or alloy thereof.

8. The contact image sensor according to claim 1, wherein the first insulation structure and the second insulation structure are not opaque.

9. The contact image sensor according to claim 1, wherein the sensing units and the OLED units are interleaved from the top view of the contact image sensor.

10. The contact image sensor according to claim 1, wherein the light beams from the OLED units are reflected by an object contacting the transparent insulation structure and pass through the focusing units to be received by the sensing units.

11. The contact image sensor according to claim 9, wherein the sensing units are activated sequentially to receive reflected light beams out of the OLED units.

12. The contact image sensor according to claim 10, wherein when one sensing unit is activated, one or more corresponding OLED units are turned on so that the best quality of an image formed by the reflected light beams are able to be obtained.

13. The contact image sensor according to claim 1, wherein the transparent conductive layer is made of Indium Tin Oxide (ITO).

14. The contact image sensor according to claim 1, wherein the focusing units are formed in a layer of opaque material.

15. The contact image sensor according to claim 13, wherein the opaque material is metal.

16. The contact image sensor according to claim 1, wherein the focusing unit is a pinhole.

17. The contact image sensor according to claim 1, wherein the conductive metal layer comprises a plurality of wires, each connecting to a row or a column of OLED units.
